(19) United States
(12) Patent Application Publication
(10) Pub. No.: US 2010/0276699 A1
(43) Pub. Date: Nov. 4, 2010

(54) Silicon Carbide and Related Wide Bandgap Semiconductor Based Optically-Controlled Power Switching Devices

(75) Inventors: Feng Zhao, Columbia, SC (US); Tangali S. Sudarshan, Columbia, SC (US)

Correspondence Address: DORITY & MANNING, P.A., POST OFFICE BOX 1449, GREENVILLE, SC, 29602-1449, US

(73) Assignee: University of South Carolina, Columbia, SC (US)

(21) Appl. No.: 12/773,369

(22) Filed: May 4, 2010

Related U.S. Application Data
(60) Provisional application No. 61/215,296, filed on May 4, 2009.

(51) Int. Cl. H01L 29/06; H01L 29/24; H01L 29/20

(52) U.S. Cl. 257/76; 257/77; 257/E29.005; 257/E29.104; 257/E29.089

(57) ABSTRACT

An optically-controlled power switch for use as an electrical switch is generally provided. The device can include a wide bandgap semiconducting material defining a stack having a p-n junction, a metal mask overlying the top surface of the stack and defining at least one opening to allow light to pass through the metal mask; a first lead wire connected to the metal stack; and a second lead wire connected to the bottom surface of the stack.

### PRIORITY INFORMATION

The present application claims priority to U.S. Provisional Patent Application No. 61/215,296 filed on May 4, 2009 titled “Silicon Carbide and Related Wide Bandgap Semiconductor Based Optically-Controlled Power Switching Devices” of Feng Zhao and Tangali Sudarshan, the disclosure of which is incorporated by reference herein.

### BACKGROUND

Optically-controlled power devices are attractive to different applications such as pulsed power generation, impulse radar control, electrical engine control, and in general, dc/dc or ac/dc converters, etc. General schematics of (a) a conventional electrically-driven power switch and (b) an optically-controlled power switch are shown in FIG. 1. As shown, the conventional electrically-driven power switch contains a switch that opens and closes upon applied electrical bias from the electrical source. Alternatively, the optically-controlled power switch contains a switch that opens and closes upon applied light from the optical source. Compared to conventional gas and mechanical switches, and electrically-driven power devices, optically-controlled power devices provide some key advantages, including fast switching, large dynamic range, negligible time jitter response, high reliability, low inductance, optical isolation of the trigger, high thermal capacity and immunity of noise.

Conventionally used materials for optically-controlled power devices are silicon (Si) and gallium arsenide (GaAs). Although optical switches with high speed and high power handling capability have been demonstrated, these switches are not able to meet the requirements of all power devices. For example, the performance of these devices are limited by the relatively low breakdown strength, low thermal conductivity, and other related properties of the materials. For instance, an ideal high-voltage switch (MOSFET) should have no resistance in its “on state”, when it conducts electricity. Conversely, in its “off state”, it should block an infinitely high voltage and prevent any electrical current from flowing through it. In reality, however, this is impossible. Doubling the voltage blocking capability typically leads to an increase in the on-state resistance by a factor of five, a physical law often referred to as the silicon limit for performance.

Compared to Si and GaAs, SiC and related wide bandgap semiconductors have two to three times larger bandgap energy, which makes their intrinsic carrier density (nᵢ) more than 10 orders of magnitude smaller at room temperature. Reverse junction leakage and dark current are known to be dramatically reduced by such a small nᵢ. The breakdown electric field of wide bandgap semiconductors is also an order of magnitude higher than that of Si and GaAs, which means that with the same doping, wide bandgap semiconductor based power devices can block roughly 100 times more reverse voltage. The thermal conductivity of wide bandgap semiconductors especially SiC is higher than that of Si and GaAs, even higher than some metals like copper. With this high heat conduction across the material, devices have high power handling capability and can be operated at high junction temperatures.

Therefore, a need exists for optically-controlled power switches based on SiC and related wide bandgap semiconductors that can take the advantages of both wide bandgap semiconductor materials and optically-controlled power devices.

### SUMMARY

Objects and advantages of the invention will be set forth in part in the following description, or may be obvious from the description, or may be learned through practice of the invention.

An optically-controlled power switch for use as an electrical switch is generally provided. The device can include a wide bandgap semiconducting material defining a stack having a p-n junction, a metal mask overlying the top surface of the stack and defining at least one opening to allow light to pass through the metal mask; a first lead wire connected to the metal stack; and a second lead wire connected to the bottom surface of the stack.

Other features and aspects of the present invention are discussed in greater detail below.

### BRIEF DESCRIPTION OF THE DRAWINGS

A full and enabling disclosure of the present invention, including the best mode thereof to one skilled in the art, is set forth more particularly in the remainder of the specification, which includes reference to the accompanying figures, in which:

FIG. 1 shows a general schematic of (a) a conventional electrically-driven power switch compared to (b) an optically-controlled power switch;

FIG. 2 shows exemplary schematic cross-section diagrams of optically-controlled conductors on an n-type substrate;

FIG. 3 shows exemplary schematic cross-section diagrams of optically-controlled P-N diodes having (a) a mesa structure and (b) a planar structure;

FIGS. 4a, 4b, and 4c shows exemplary mask patterns configured for metal contact on optically-controlled PN diodes with probing pad at the center;

FIG. 5 shows exemplary schematic cross-section diagrams of optically-controlled BJT-like devices having (a) a mesa structure and (b) a planar structure;

FIG. 6 shows exemplary schematic cross-section diagrams of optically-controlled IGBT-like devices having (a) a mesa structure and (b) a planar structure;

FIG. 7 shows an image of an exemplary SiC optically-triggered PIN diode as described in the Examples;

FIG. 8 shows forward and reverse I-V characteristics of exemplary SiC PiN diodes as described in the Examples;

FIG. 9 shows an exemplary diagram of an optical switching test circuit; and

FIG. 10 shows results of an exemplary diagram of an optical switching test circuit as described in the Examples.

### DETAILED DESCRIPTION

Reference now will be made to the embodiments of the invention, one or more examples of which are set forth below. Each example is provided by way of an explanation of the invention, not as a limitation of the invention. In fact, it will be apparent to those skilled in the art that various modifications and variations can be made in the invention without departing from the scope or spirit of the invention. For instance, features illustrated or described as one embodiment can be used on another embodiment to yield still a further embodiment. Thus, it is intended that the present invention cover such modifications and variations as come within the scope of the appended claims and their equivalents. It is to be understood by one of ordinary skill in the art that the present discussion is a description of exemplary embodiments only, and is not intended as limiting the broader aspects of the present invention, which broader aspects are embodied exemplary constructions.

Optically-controlled power devices and their methods of manufacture and of use are generally provided. For example, the optically-controlled power devices can include silicon carbide (SiC) and related wide bandgap semiconductors such as diamond, aluminium nitride (AlN), gallium nitride (GaN), boron nitride (BN), etc. and mixtures thereof. As used herein, the term “wide bandgap semiconductors” refers to semiconductor materials with electronic band gaps greater than about 1.7 electronvolt (eV), such as greater than about 2 eV (e.g., about 3 eV to about 7 eV).

Wide bandgap semiconductors can provide a semiconductor material doped with p- and n-materials to form a diode. As shown in the Figures, the application of light causes electrons (e⁻) to move from the p-type layer to the n-type layer, and holes (h⁺) to move from the n-type layer to the p-type layer. Thus, upon application of light, a current is allowed to move through the thickness of the diode.

The optically controlled power devices are generally voltage blocking when in the off position (i.e., the “open” position of the switch). For example, a single optically controlled power device can be configured to block up to about 20 kV (i.e., 20,000 volts), such as about 5 kV to about 20 kV. In particular embodiments, a single optically controlled power device can be configured to block about 10 kV to about 18 kV, such as from about 15 kV to about 17.5 kV.

In one particular embodiment, multiple optically controlled power devices can be stacked in series to create an assembled power switch configured to block voltage at any desired amount, since the voltage blocking ability of the series of switches is the sum of the individual voltage blocking ability of each individual optically controlled power device in the series. For example, five optically controlled power devices connected in series can block up to about 100,000 kV (i.e., 5 times the voltage blocking of a single optically controlled power device). However, each of the multiple optically controlled power devices in the series must be opened and closed substantially simultaneously to effectively work in unison as a single switch.

In another embodiment, multiple optically controlled power devices can be stacked in parallel to increase the current handling ability of the devices, since the total current passing through the multiple optically controlled power devices is the sum of the currents through the individual devices. Of course, any combination of series and parallel devices can be connected (e.g., wired) together depending on the switching characteristics desired in the final device.

Exposing the optically controlled power devices to light can “close” the switch, allowing current to flow freely through the device. Due to the nature of the device, the device can alternate between the open position (i.e., voltage blocking) and the “closed” position (i.e., voltage flowing) extremely quickly. For example, turn-on/off response time is in the range of pico- to micron-seconds, for example about 1 picosecond to about 1,000 microseconds, such as about 500 picoseconds to about 500 microseconds.

The optically-controlled power devices presently disclosed can have several different structures incorporating a P-N junction. When P-N junction is reverse biased, there is a depletion region formed and no current flow in the external circuit, so the switch is “open”. Absorption of light in the P-N junction produces electron-hole pairs. Pairs produced in the depletion region, or within a diffusion length of it, will eventually be separated by the electric field, leading to current flow in the external circuit as carriers move across the depletion layer, so the switch is “closed” and allows current to flow through the P-N junction.

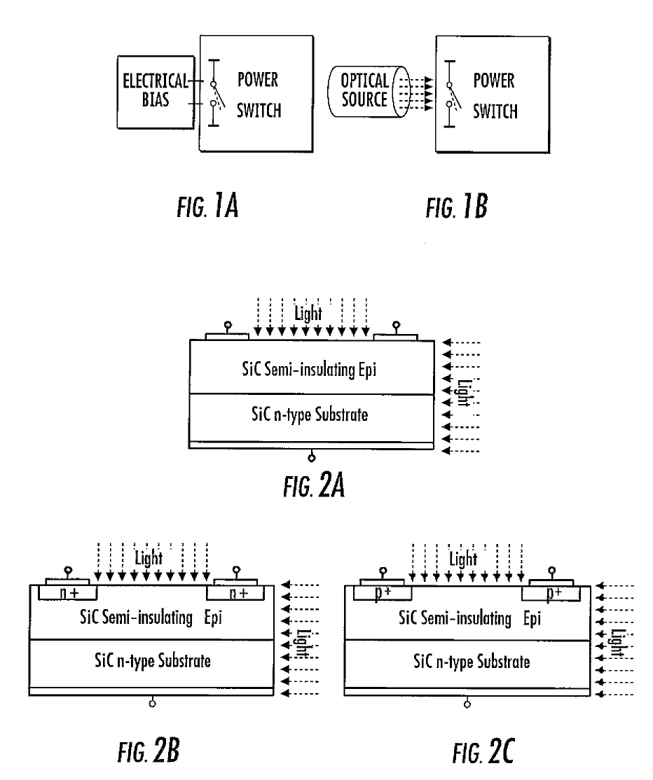

As stated, the optically-controlled power device can respond to the application of light to its surface or side (as shown in FIG. 2), resulting in the opening of the switch. The particular wavelength of light that generates a response can depend on the particular material used to form the stack. In particular embodiments, the wavelength of the light applied to the device to solicit a response generally corresponds to the bandgap energy of the material used to form the device,

$$λ = \frac{hc}{{E}_{g}} = \frac{1.24}{{E}_{g} ( e V )} [ μ m ] ,$$

where λ is the wavelength of light, h is the plank constant, c is the speed of light, and E_{g} is the bandgap energy of the semiconductor. For example, if constructed from silicon carbide (SiC) having a bandgap of about 3.2 eV, the light wavelength in the UV spectrum could solicit a response from the device. For wavelengths shorter than λ, the incident radiation is absorbed by the semiconductor, and hole-electron pairs are generated.

The materials used to construct the optically-controlled power device structure can be wide bandgap semiconducting materials, such as silicon carbide (SiC), gallium nitride (GaN), aluminum nitride (AlN), boron nitride (BN), and diamond, etc., as well as other semiconductor materials such as silicon (Si) and gallium arsenide (GaAs), and combinations thereof.

The optically-controlled power devices generally include at least one P-N junction to form the switch. As know in the art, a P-N junction is formed by joining p-type and n-type semiconductors together in very close contact. The term junction refers to the boundary interface where the two regions of the semiconductor meet. If they were constructed of two separate pieces, a grain boundary is introduced, so p-n junctions are generally created in a single crystal of semiconductor by doping, for example by ion implantation, diffusion of dopants, or by epitaxy (growing a layer of crystal doped with one type of dopant on top of a layer of crystal doped with another type of dopant).

In one particular embodiment, the p-n junction can be formed in the wide bandgap semiconducting material by doping suitable p-type and n-type dopants into the semiconducting material. For example, nitrogen (N) atoms can be used as n-type dopants, and aluminum (Al) atoms can be used as p-type dopants. Dopants can be added into the semiconductor materials during epitaxial growth of the materials or by high energy ion-implantation or diffusion processes.

Particular structures suitable for the optically-controlled power devices can include single P-N junctions or multiple P-N junctions on the same stack. For example, the optically-controlled power devices can have a P-N-P stack or N-P-N stack (i.e., a “bi-polar” stack), a P-N-P-N stack or N-P-N-P stack (i.e., a “tri-polar” stack), and so on.

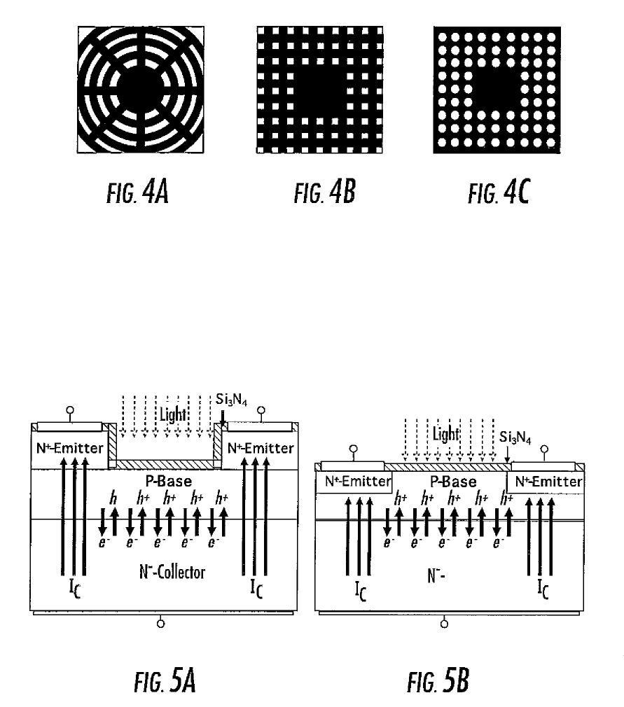

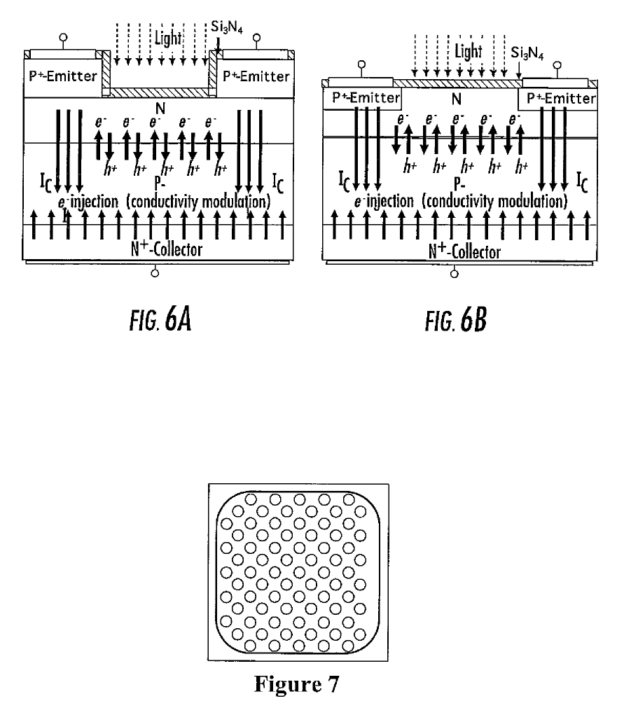

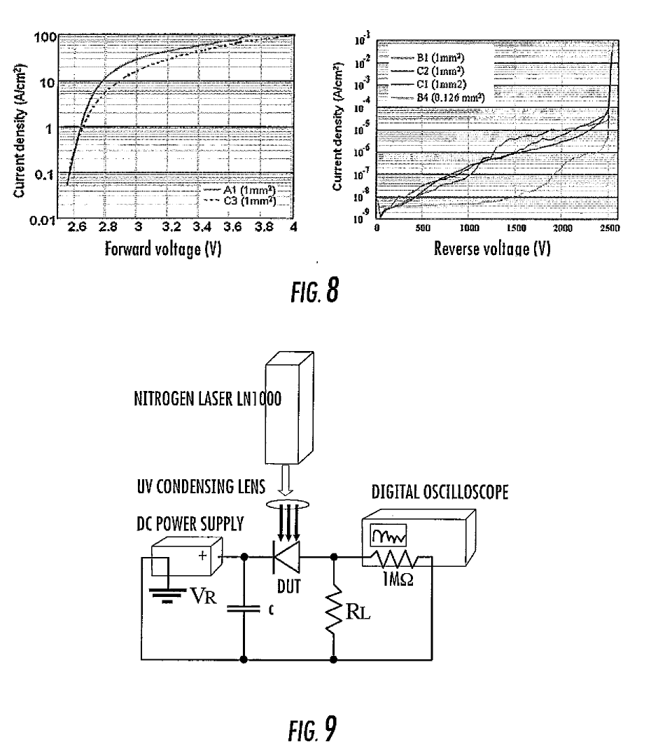

For example FIG. 2 shows schematically an exemplary optically-controlled power device structure with a highly resistive epitaxial layer (shown as the exemplary SiC semi-insulating epi-layer) grown on top of a SiC n-type substrate. Light can be exposed from the top and/or the sides to trigger the switch. Compared to conventional SiC bulk photoconductors which require bulk SiC semi-insulating materials, the switches in FIG. 2 have the advantages of lower cost and higher material quality. In FIG. 2(a), the ohmic contacts are made directly to the SiC semi-insulating epitaxial layer. In FIG. 2(b and c), highly-doped n+ or p+ regions are formed on the surface of the semi-insulating epitaxial layer by ion-implantation and annealing to reduce contact resistance and therefore the total switching loss. The epitaxial layer can generally be a thin film layer on the SiC n-type substrate. As used herein, the term “thin film” generally refers to a film layer having a thickness of less than about 25 micrometers (μm). Exemplary mask patterns configured for metal contact on the top, light absorbing surface are shown in FIG. 4.

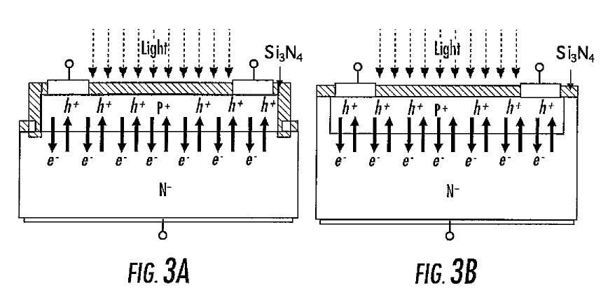

For example, FIG. 3 shows schematically another exemplary optically-controlled power device structure with a (a) mesa and (b) planar P-N junction. The p-type region can be formed by epitaxial growth or by ion-implantation or by diffusion. Electron and hole pairs (EHPs) are generated in and close (within one diffusion length) to the depletion region in the P-N junction by photons from the optical source (for example, ultraviolet light). As shown, the p⁺-type layer can accept holes (h⁺) from and provide electrons (e) to the N⁻-type layer, which is collecting electrons (e⁻) from and providing holes (h⁺) to the p⁺-type layer. To allow the light to penetrate into the depletion region, both ohmic contact metal grid and a window layer (e.g., transparent indium tin oxide (ITO)) can be used for the best optical absorption efficiency. Exemplary mask patterns configured for metal contact on the top, light absorbing surface are shown in FIG. 4.

FIG. 5 shows another exemplary optically-controlled power device structure with (a) a mesa and (b) planar emitter. It is similar to the conventional npn bipolar junction transistor (BST) structure but without base contacts. The design is for more efficient light absorption since the base current is generated by light trigger instead of electrical bias. The thickness and doping density of each epitaxial layer as well as the lateral layout especially the area between two neighboring emitter stripes can determine the performance of reverse blocking voltage, current gain and optical response. As shown, the p-type layer can accept holes (h⁺) from and provide electrons (e⁻) to the N⁻-type layer, which is collecting electrons (e⁻) from and providing holes (h⁺) to the p⁺-type layer. Additionally, the N⁺-emitter layer can provide additional electrons to the p-type layer, facilitating the flow of electrons (e⁻) from the p-type layer to the N⁻-type collector layer, resulting in current flow through the device (I_{C}) when exposed to light. Exemplary mask patterns configured for metal contact on the top, light absorbing surface are shown in FIG. 4.

FIG. 6 shows another optically-controlled power device structure with (a) a mesa and (b) planar emitter. It is similar to the conventional insulated gate bipolar transistor (IGBT) structure with a p-n-p-n stack taking advantage of the availability and lower resistance of n-type substrate, but without gate bias and gate dielectric. The current conducted between collector and emitter is generated optically instead of by the electrical field induced inversion channel. The absence of gate oxide and gate bias substantially reduces gate leakage. The absence of inversion channel reduces the conduction loss since the devices do not suffer from the low channel mobility. The extra n⁺ substrate injects electrons into the p-type drift region to modulate the conductivity and further reduces the conduction loss of the devices. As shown, the p⁻-type layer can accept holes (h⁺) from and provide electrons (e⁻) to the N-type layer, which is collecting electrons (e⁻) from and providing holes (h⁺) to the p⁻-type layer. Additionally, the N⁺-collector layer can provide additional electrons to the p⁻-type layer, inhibiting conduction loss by flooding electrons into the p⁻-type layer and facilitating current flow through the device (I_{C}) when exposed to light. The P⁺-emitter layer can provide holes to the N-type layer further facilitating current flow through the device (I_{C}) when exposed to light.

The mesa-type structures discussed above generally has a structure where the top epitaxial layer defines an edge in the z-direction (i.e., the direction defining the thickness of the device), due to epitaxial growth of the final semiconducting layer on the substrate, as shown in FIGS. 2(a), 3(a), 5(a), and 6(a). On the other hand, the planar-type structures have the top semiconductor layer implanted into the underlying layer to form a more planar device on its top surface, as shown in FIGS. 2(b), 3(b), 5(b), and 6(b).

No matter the particular structure of the optically-controlled power device, each device is connected to a pair of lead wires, one at the top of each structure and the other at the bottom of each structure. In one particular embodiment, the positive lead wire is attached to the top layer (i.e., contacting the p-type layer), while the negative lead wire is attached to the bottom layer. The top of each structure, however, must remain somewhat transparent to allow light to reach the underlying structure. FIG. 4 shows exemplary mask patterns configured for metal contact on the top surface of the optically-controlled PN diodes with a probing pad at the center for connection to a lead wire. Each of these patterns allow for light to pass through the openings (not colored regions) defined in the mask enabling the optically-controlled power device to respond to the application of light. The mask can be a metal mask constructed from any suitable conductive metal material, where metal is present in the dark regions shown on the mask. Additionally, each of these patterns allows the electrical signal to substantially uniformly traverse the entire surface of the mask. For example, FIG. 4(a) shows multiple metal rings interconnected together. FIGS. 4(b) and 4(c) show a mask having rectangular and circular openings, respectively, defined in the mask pattern in a substantially uniform pattern.

The metal mask contacts the top layer (e.g., the p-type layer) of each structure. The area uncovered by the mask (i.e. the area of the structure exposed through the openings defined by the mask) can be left open and exposed or covered by a surface pacification layer. The surface pacification layer is generally transparent to light for switching the device open and closed, while avoiding surface voltage flashover. For example, the surface pacification layer can have a bandgap energy that is substantially similar to that of the wide bandgap semiconducting material of the device structure (e.g., within about 10% of the bandgap energy of the wide bandgap semiconducting material). Although each of FIGS. 2, 3, 5, and 6 show the surface passification layer as including silicon nitride (Si₃N₄), the surface pacification layer can include any other suitable material, including but not limited to, silicon dioxide (SiO₂), aluminium oxynitride (AlON), etc., and combinations thereof.

The bottom of the device can also be connected to a metal contact. However, the bottom contact can be a solid metal layer since no light needs to pass through this contact.

In one embodiment, such as shown in FIGS. 2, 3, 5, and 6, no gate oxide layer is required in the structure.

Methods of forming the optically-controlled power switches are also generally provided. In one embodiment, a semiconducting epitaxial layer can be formed on a wide bandgap semiconductor material, and metal contacts can be made on either side of the thickness of the device, such as shown in FIG. 2(a). Optionally, an n-type or p-type epitaxial layer can be formed between the semiconducting epitaxial layer and the top metal contact, as shown in FIGS. 2(b) and 2(c), respectively.

### EXAMPLES

### 1. Device Fabrication

The n⁻ epitaxial layer with a thickness of 15 μm and a concentration of 5×10¹⁵ cm⁻³ was grown on a commercial 3-inch 8° off-axis n-type 4H—SiC conductive substrate. The wafer was diced into pieces with an area of 1.2 by 1.2 cm² for device fabrication. The p-type region and junction termination extension (JTE) region were formed by an Al and B implantation followed by annealing process at 1510° C. for 30 min in argon ambient of 700 torr. Ti/Al/Ti/Ni metal stack for p-type anode contact with openings on the top for light penetration was formed by e-beam evaporation and lift-off, and Ni was deposited on the back of the sample for n-type cathode contact. Both n- and p-type ohmic contacts were prepared by rapid thermal annealing (RTA) at 1000° C. for 1 min in the high-purity nitrogen gas.

### 2. Measurements

The dc current-voltage (I-V) characterization was performed with a semiconductor parameter analyzer to qualify the transistor for optical switching tests. FIG. 8 shows the forward and reverse I-Vs of diodes from different locations. The devices deliver 100 A/cm² with a forward voltage drop of 3.7 to 4 V, and are capable of blocking 2500 V with a leakage current of 10⁻⁵ A/cm².

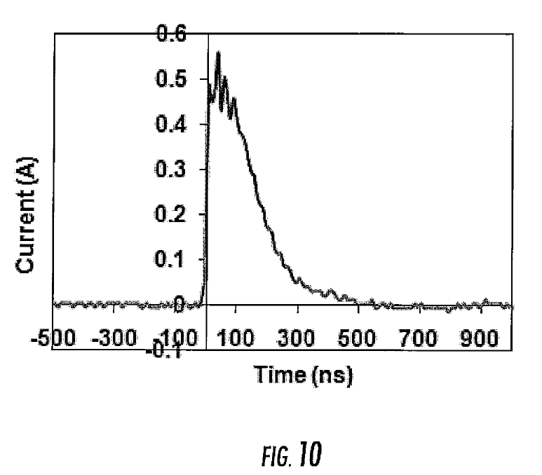

The setup of optical switching included an optical source is a Nitrogen laser with 337.1 nm wavelength, 600 ps pulse-width, and 1.2 mJ energy per pulse. The absorption coefficient α of such a UV laser is 730 cm⁻¹ (α⁻¹=14 μm) in 4H—SiC at room temperature, which is suitable for testing our diodes with a 15 μm thick n⁻ drift layer. The optical switching test circuit and result is shown in FIG. 9. The diode successfully switched 1000 V with the photocurrent pulse full width at half maximum (FWHM) about 180 ns, the full width about 300 ns, and the rise time about 10 ns, fall time about 200 ns, as shown in FIG. 10

### 3. Conclusion

Optically-triggered SiC PiN diodes with a 2500 V blocking voltage were fabricated. When triggered by a UV laser, the devices are capable of switching 1000 V with a photocurrent pulse of 180 ns FWHM and 300 ns full width.

These and other modifications and variations to the present invention may be practiced by those of ordinary skill in the art, without departing from the spirit and scope of the present invention, which is more particularly set forth in the appended claims. In addition, it should be understood the aspects of the various embodiments may be interchanged both in whole or in part. Furthermore, those of ordinary skill in the art will appreciate that the foregoing description is by way of example only, and is not intended to limit the invention so further described in the appended claims.

What is claimed:

1. An optically-controlled power switch for use as an electrical switch, the device comprising:
a wide bandgap semiconducting material defining a stack having a p-n junction, wherein the stack defines a top surface and a bottom surface;
a metal mask overlying the top surface of the stack, wherein the metal mask defines at least one opening to allow light to pass through the metal mask;
a first lead wire connected to the metal stack; and
a second lead wire connected to the bottom surface of the stack.

2. The device of claim 1, wherein the wide bandgap semiconducting material comprises silicon carbide.

3. The device of claim 1, wherein the wide bandgap semiconducting material comprises, aluminium nitride, gallium nitride, boron nitride, or mixtures thereof.

4. The device of claim 1, wherein the wide bandgap semiconductor has an electronic band gap of about 2 eV to about 7 eV.

5. The device of claim 1, wherein the stack has a single p-n junction.

6. The device of claim 1, wherein the stack is a bi-polar stack having p-n-p junctions.

7. The device of claim 1, wherein the stack is a tri-polar stack having a p-n-p-n junctions.

8. The device of claim 1, wherein the stack has a mesa structure.

9. The device of claim 1, wherein the stack has a planar structure.

10. The device of claim 1, further comprising:
a surface pacification overlying the top surface of the stack in exposed areas of the stack corresponding to the openings in the metal mask.

11. The device of claim 10, wherein the surface pacification layer comprises silicon nitride.

12. The device of claim 1, wherein the p-n junction is formed by a p-type layer and an n-type layer, wherein the p-type layer comprises p-type dopants and the n-type layer comprises n-type dopants.

13. The device as in claim 12, wherein the p-type layer has a thickness of about 0.5 μm to about 25 μm, and the n-type layer has a thickness of about 0.5 μm to about 25 μm.

14. The device as in claim 1, wherein the device has a mesa structure.

15. The device as in claim 1, wherein the device has a planar structure.
